(19) United States
(12) Patent Application Publication
(10) Pub. No.: US 2023/0334186 A1
(43) Pub. Date: Oct. 19, 2023

(54) Generation of Preliminary Designs and Analysis of Antenna-Supporting Structures

(71) Applicant: Meta Platforms, Inc., Menlo Park, CA (US)

(72) Inventors: Vishvas Samuel Suryakumar, Sunnyvale, CA (US); Ling-Bing Kung, Arcadia, CA (US); Zhang Liu, Oak Park, CA (US); Abhishek Tiwari, Oak Park, CA (US); Jack Marriott, Thousand Oaks, CA (US)

(21) Appl. No.: 17/013,928

(22) Filed: Sep. 8, 2020

Related U.S. Application Data
(60) Provisional application No. 62/950,213, filed on Dec. 19, 2019.

(51) Int. Cl. H01Q 1/00; H01Q 1/12; H04W 16/18

(52) U.S. Cl. CPC H01Q 1/005; H01Q 1/1242; H04W 16/18

(57) ABSTRACT

Apparatuses, methods, and systems for generation of antenna tower structures are disclosed. One method includes receiving structure requirements of a tower, iterating a design of the tower, including selecting tower design features, determining a structural model from the structure requirements and the tower design features, defining an outline of the tower based on structure requirements and tower design features, defining nodal points of the design of the tower based on the outline, defining line-elements of the design of the tower based on the nodal points, performing low-order structural analysis based on the structural model and a modeled behavior assigned to the line-elements including determining a wind load for each line element, determining nodal displacements and material failure indices based at least on the wind load for each line element, and redetermining the structural model when the nodal displacements and material failure indices indicate failure.

### RELATED APPLICATIONS

This patent application claims priority to U.S. Provisional Patent Application Ser. No. 62/950,213, filed Dec. 19, 2019, which is herein incorporated by reference.

### FIELD OF THE DESCRIBED EMBODIMENTS

The described embodiments relate generally to wireless communications. More particularly, the described embodiments relate to systems, methods and apparatuses for generation of preliminary designs and analysis of antenna-supporting structures.

### BACKGROUND

The demand for communications towers has notably increased in recent times on account of the rapid surge in worldwide data traffic. With the introduction of advances in wireless communication technology, such as 5G, global mobile traffic is set to rapidly grow in coming years. Although, much of the investment focus is trending toward smaller towers in urban areas, significant investment has also been made in rural areas. Such investments are expected to catalyze the rural economy and lower unemployment rates.

Innovations in tower design, construction and maintenance have a direct impact not just in accelerating the growth of the tower industry, but ultimately, on the state of worldwide connectivity. As an example, carbon-fiber is making an entrance to the steel-dominated tower industry. Innovation in tower design methods and software analysis tools is another potential means of impact. Many tower design software packages currently exist. However, the primary use case is for detailed design and comprehensive structural analysis. Currently, no tools exist for preliminary tower design and analysis that may be useful for decision-making at the conceptual design/planning stage. In emerging markets, where specialized tower expertise (that is, tall guyed towers) may be lacking, such a tool may assist in quickly producing preliminary designs given high level requirements or to quickly check the structural integrity/capacity of existing structures. This capability is also be useful for network planning tools with the ability to rapidly trade structural capacity with deployment cost and coverage.

It is desirable to have methods, apparatuses, and systems for generation of preliminary designs and analysis of antenna-supporting structures.

### SUMMARY

An embodiment includes a method. The method includes receiving, by a processor, structure requirements of a tower, and iterating, by a non-linear optimizer of the processor, a design of the tower, including selecting tower design features. An embodiment includes determining a structural model from the structure requirements and the tower design features, by defining an outline of the tower based on structure requirements and tower design features, defining nodal points of the design of the tower based on the outline, and defining line-elements of the design of the tower based on the nodal points. Further, an embodiment includes performing, by the processor, low-order structural analysis based on the structural model comprising assigning a modeled behavior to the line-elements including determining a wind load for each line element, determining nodal displacements and material failure indices based at least on the wind load for each line element, and redetermining, by the non-linear optimizer, the structural model when the nodal displacements and material failure indices indicate failure.

An embodiment includes a network. The network includes a database, and one or more computing devices. The one or more computing devices are interfaced with the database and operative to receiving structure requirements of a tower. A non-linear optimizer of the one or more computing devices operates to iterate a design of the tower, comprising the non-linear optimizer operating to tower design features, determine a structural model from the structure requirements and the tower design features, define an outline of the tower based on structure requirements and tower design features, define nodal points of the design of the tower based on the outline, define line-elements of the design of the tower based on the nodal points, perform low-order structural analysis based on the structural model and a modeled behavior assigned to the line-elements comprising determining a wind load for each line element, and determine nodal displacements and material failure indices based at least on the wind load for each line element, wherein the non-linear optimizer operates to redetermine the structural model when the nodal displacements and material failure indices indicate failure.

Other aspects and advantages of the described embodiments will become apparent from the following detailed description, taken in conjunction with the accompanying drawings, illustrating by way of example the principles of the described embodiments.

### BRIEF DESCRIPTION OF THE DRAWINGS

FIG. 1 shows a network that includes a plurality of wind sensors, a wind sensor information database, and a computing device operative to generate an antenna tower structure design, according to an embodiment.

FIG. 2 is a block diagram of a system for generating an antenna tower structure design, according to an embodiment.

FIG. 3 shows tower design features, according to an embodiment.

FIG. 4 shows an outline of a tower, according to an embodiment.

FIG. 5 is a block diagram of a system for generating an antenna tower structure design, according to another embodiment.

FIG. 6 illustrates several possible antenna tower structure designs and design variables and constraints associated with each of the possible antenna tower structure designs, according to an embodiment.

FIG. 7 is a flow chart that includes steps of a method of generating an antenna tower structure design, according to an embodiment.

### DETAILED DESCRIPTION

The embodiments described include methods, apparatuses, and systems for generation of preliminary designs and analysis of antenna-supporting structures. At least some embodiments include iterating, by a non-linear optimizer of the processor, a design of a tower for an antenna. The iterating includes determining a structural model from structure requirements and tower design features, defining an outline of the tower based on structure requirements and tower design features, defining nodal points of the design of the tower based on the outline, and defining line-elements of the design of the tower based on the nodal points. Further, the iterating includes performing low-order structural analysis based on the structural model and a modeled behavior assigned to the line-elements including determining a wind load for each line element, determining nodal displacements and material failure indices based at least on the wind load for each line element, and redetermining, by the non-linear optimizer, the structural model when the nodal displacements and material failure indices indicate failure.

For at least some embodiments, prior to design, the type of tower is specified. In the industry, there are typically the following types: 1) Monopoles 2) Self-supported and 3) Guyed. Monopoles are cantilevered hollow structures that extend for heights up to 60 m. Self-supported structures are lattice towers that are used for taller tower designs up to 120 m. Guyed towers feature a slender mast with lateral stability provided by tensioned guy cables that are anchored to the ground. These towers are cost-effective implementations of tall towers and sometimes extend to heights up to 500 m. Both monopoles and self-supported are typically used in urban settings where land leasing costs are not cost-optimal. Guyed towers are more often used in rural areas since a large area of land may be required. In addition to tower type, height and antenna loading, classifications for structural reliability/hazards and terrain (to account for wind exposure) also need to be specified for the design. At least some embodiments, includes a rapid-design tool to capture this process. Preliminary designs are obtained using 1) a simplified finite-element representation of the structure to model structural behavior and 2) a heuristic optimization method to minimize tower cost while satisfying design constraints.

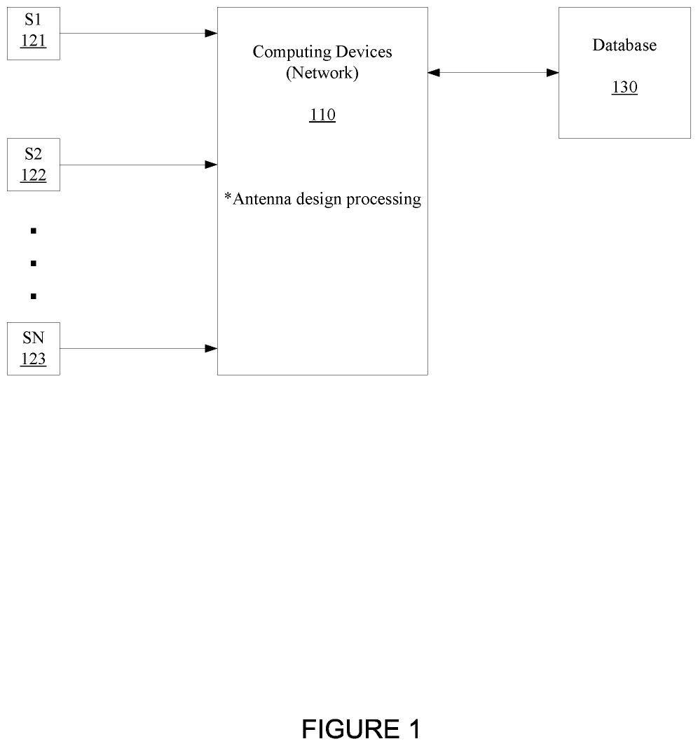

FIG. 1 shows a network that includes a plurality of wind sensors 121, 122, 123, a wind sensor information database 130, and a computing device 110 operative to generate an antenna tower structure design, according to an embodiment. At least some of the described embodiments utilize wind and sensed wind information over time to aid in the design of antenna tower structures. As shown in FIG. 1, for an embodiment, the wind information is sensed and collected over time. The sensed wind information (or a processed result of the sensed wind information) is stored in the database 130 for future use in the analysis of antenna tower structure designs. As the antenna tower structures are designed to be deployed in varying locations for varying amounts of time, sensed wind information from the varying locations and over varying periods of time are sensed and stored. For an embodiment, the sensed wind information is utilized in the design of antenna-supporting tower structures.

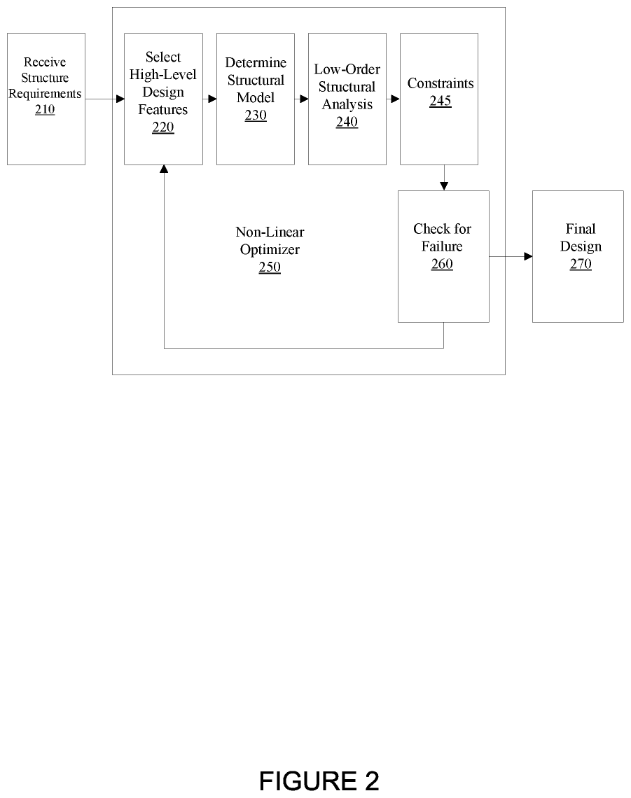

FIG. 2 is a block diagram of a system for generating an antenna tower structure design, according to an embodiment. This system is operable on one or more computing devices. To initiate design of an antenna tower, structural requirements 210 of the antenna tower are received. For an embodiment, the structure requirements of the antenna tower include high-level design parameters including at least one of a tower height, a tower type (monopole, self-supported or guyed), a mast cross-section (triangle or square), loading (windspeed, gust amplification) or reliability (risk to property in case of crash). For an embodiment, the structural requirements 210 are generated by network planners and communicated, for example, to tower construction sub-contractors to begin a design and build-out of the antenna tower. For an embodiment, the structural requirements 210 may relaxed or tightened to optimize costs.

A non-linear optimizer 250 (operating on a processor or one or more computing devices) receives the structural requirements 210 and initiates iterating a design of the tower. For an embodiment, the iterating includes selecting tower design features 220. For an embodiment, the tower design features include at least one of mast leg and diagonal diameters, a mast size, a number of guys, a diameter of the guys.

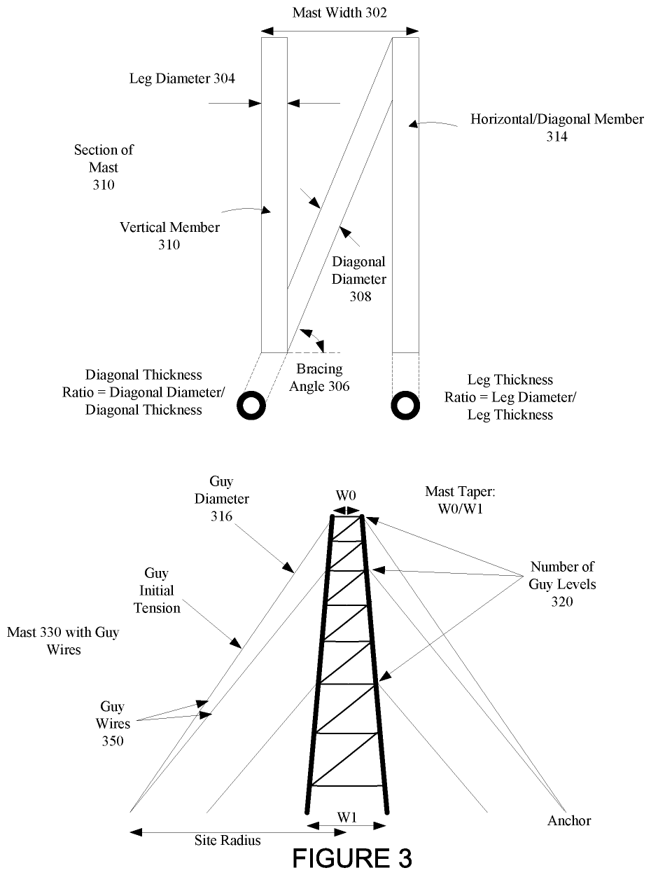

FIG. 3 shows tower design features, according to an embodiment. As shown, a section of a mast 310 of the tower includes vertical members 312 and horizontal/diagonal members 314 (horizontal & diagonal members are also called bracing members). For an embodiment, the vertical members 312 and the horizontal/diagonal members 314 are essentially steel pipes. For an embodiment, a diameter 304 of the mast leg is the external diameter of the vertical member 312 and the diagonal diameter 308 is the external diameter of the horizontal/diagonal member 314. For an embodiment, the mast size or width is the side length of the mast (shown as mast width, W1, W2, and 302). For an embodiment, the number of guys is the number of guy levels 320 attaching to the mast 330. That is, the number of levels (altitude) of connections of the guys to the mast. For an embodiment, the diameter of the guys is the external diameter 316 of the guy wires 350.

For an embodiment, a diagonal thickness ratio can be determined by a ratio of the diagonal diameter 308 to a diagonal thickness (thickness of the steel portion of the horizontal/diagonal members 314), and a leg thickness can be determined by a ratio of the leg diameter 304 to a leg thickness (thickness of the steel portion of the leg members 312). A bracing angle 306 is defined by an angle between the vertical members 312 and the horizontal/diagonal member 314. A mast taper can be determined as a ratio of W0 to W1.

Referring back to FIG. 2, for an embodiment, the iterating by the non-linear optimizer 250 further includes determining a structural model 230 from the structure requirements and the tower design features. For an embodiment, determining the structural model includes defining an outline of the tower based on structure requirements and tower design features, defining nodal points of the design of the tower based on the outline, and defining line-elements of the design of the tower based on the nodal points.

As stated, the outline of the tower is defined based on the structure requirements and the tower design features. For example, the outline may determine a number of ground anchors of the antenna-supporting tower design, or associating a guy cluster to an anchor. For an embodiment, the outline of the tower includes one of a monopole, a self-supported or a guyed antenna-supporting tower design.

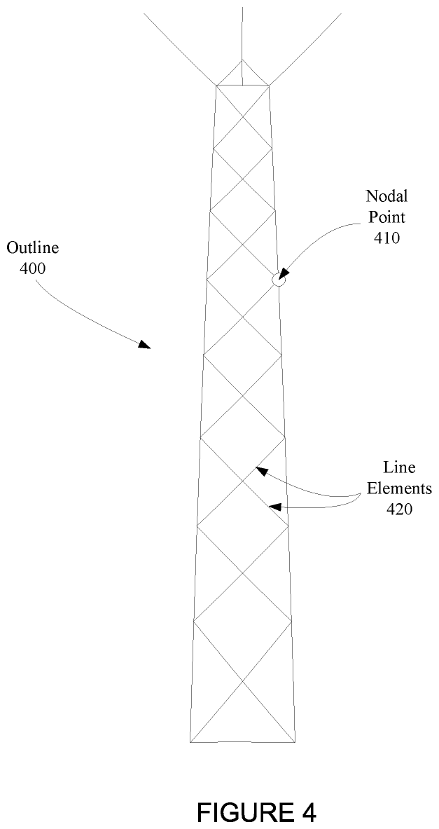

FIG. 4 shows an outline 400 of a tower, according to an embodiment. As shown, for an embodiment, the outline 400 of the tower includes a line-diagram schematic of the tower showing the different members of the tower mast (leg, bracing) and the guys. For an embodiment, the outline 400 depicts the member connectivity (where guys attach ground and mast) and location in space. Also, for an embodiment, starting from structure requirements and tower design features, and processing decides how a set of guys emanating from the mast are attached to ground. For example, for an embodiment, the average height of the set of guys from the ground should be nearly equal to the ground attachment distance from the mast.

Further, as described, determining the structural model includes defining nodal points 410 of the design of the tower based on the outline. For an embodiment, a nodal point 410 is the junction between two structural members of the antenna tower. That is, for example, a point on the structure where a guy wire meets (attaches to) the tower mast, or points of intersection of bracing members of the antenna tower. For an embodiment, the nodal points of the design of the tower are dependent on a tower type, includes a one of a monopole, self-supported or guyed. For an embodiment, for monopoles and guyed towers, the tower mast is assumed to be a single beam and is divided into at least 10 nodes between each breakpoint, wherein a breakpoint is a point where a guy cable attaches to the tower mast. For an embodiment, for guyed towers, one element with nodes on either end, is defined for each guy wire. For an embodiment, for the self-supported tower, the mast is assumed to be a lattice structure and nodes are defined at truss intersection points of the lattice structure.

Further, as described, determining the structural model includes defining line-elements 420 of the design of the tower based on the nodal points 410. For an embodiment, the line-elements 420 each include a mathematical entity representing the physical structural member extending from one nodal point to another.

Referring back to FIG. 2, for an embodiment, the iterating by the non-linear optimizer 250 further includes performing low-order structural analysis 240 based on the structural model and a modeled behavior assigned to the line-elements. For an embodiment, performing low-order structural analysis 240 includes determining a wind load for each line element, and determining nodal displacements and material failure indices based at least on the wind load for each line element.

For an embodiment, assigning the modeled behavior to the line-elements includes assigning a specific stiffness to each line-element. For an embodiment, assigning a specific stiffness to each line-element comprising associating a tension with each guy line-element or the cross-sectional geometry with each mast line-element. For an embodiment, guy cables are modeled as tension-dependent linear springs. For an embodiment, slender lattice structures for the mast are modeled as equivalent beams.

A previously stated, for an embodiment, assigning the modeled behavior to the line-elements includes assigning a stress-displacement behavior to each line-element. As previously stated, for an embodiment, line-elements are then defined from the nodal points and assigned a specific stiffness behavior. For example, a guy element (node 1 on tower, node 2 on ground) is associated with a structural stiffness that is largely tension dependent. For an embodiment, simplifications are introduced to model first-order/linear behavior. For example, guy cables are modeled as tension-dependent linear springs and slender lattice structures for the mast are modeled as equivalent beams. For an embodiment, assigning the stress-displacement behavior of each line-element indicates a degree of stress induced in a structural member as the nodal points are displaced due to either being tensioned or compressed. This provides an indication of potential material failure due to deformation of the tower.

As described, for an embodiment, performing low-order structural analysis 240 includes determining a wind load for each line element, and determining nodal displacements and material failure indices based at least on the wind load for each line element. For an embodiment, determining a wind load for each line element and antenna is based on sensed wind information. For an embodiment, the sensed wind information is generated by a plurality of wind sensor over time, wherein sensed wind information is stored in a database (as previously described and shown in FIG. 1). For an embodiment, determining the wind load is based on world-wide windspeed (based on sensed wind information) in accordance with civil engineering standards and the aerodynamic features (shape, projected area) of the line element or the antenna.

For an embodiment, the iterating by the non-linear optimizer 250 further includes redetermining, by the non-linear optimizer, the structural model when the nodal displacements and material failure indices indicate failure (check for failure 260). For an embodiment, redetermining the structural model when the nodal displacements and material failure indices indicate failure includes reselecting the tower design features before redetermining the structural model, and reperforming the low-order structural analysis, and redetermining the nodal displacements and material failure.

For an embodiment, determining a failure includes determining constraint (constraints 245) violations. For an embodiment, performing the low-order structural analysis based on the structural model and a modeled behavior assigned to the line-elements includes determining potential constraint violations. For an embodiment, the potential constraint violations include material failure of a particular structural member, or too large an antenna displacement to maintain link. That is, the antenna displacement breaks a wireless link between a first device of the antenna tower, and second device that the first device is communicating with.

The described embodiment includes the defining of a complete tower geometry from high-level tower requirements and design features. For example, this may include automatically determining a number of ground anchors (ground node point) and associate guy cluster to a specific ground anchor. For an embodiment, the ground anchor locations from the tower mast are determined such that the average height of the guy cluster (set of guys emanating from the tower mast) roughly equals the distance of the guy anchor from the mast. This is done to ensure that the tension load applied on the anchor from the guys is equally divided into uplift and side force.

As was shown and described in FIG. 1, an embodiment includes generating, by a plurality of wind sensors, wind information of a database, wherein determining the wind load includes accessing the wind information from the database.

If the checking for failure 260 of an antenna tower structure does not indicate a failure, then a final design 270 is determined or identified.

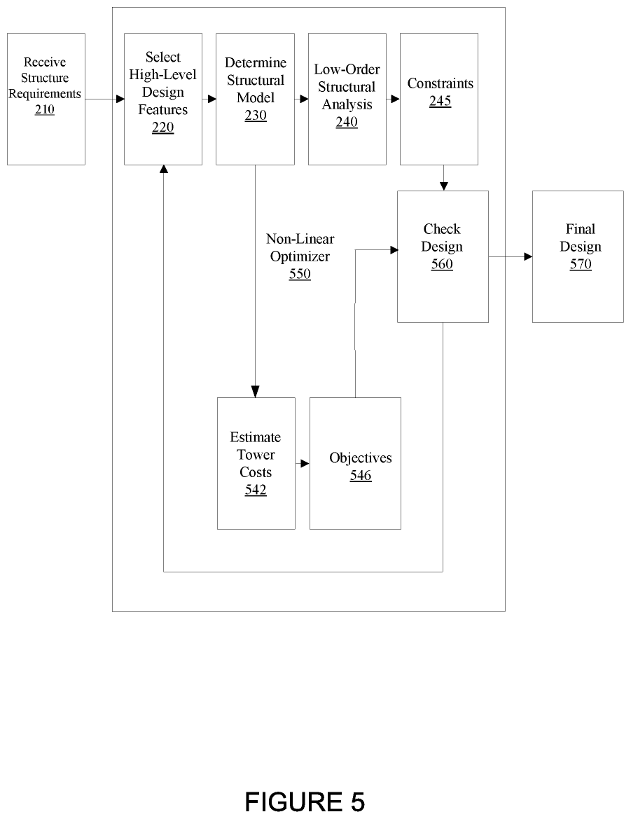

FIG. 5 is a block diagram of a system for generating an antenna tower structure design, according to another embodiment. For this embodiment, the determined structure model 230 of the non-linear optimizer 550 can be used to estimate tower costs 542. For an embodiment, the cost can be estimated, for example, based on user-input unit costs for steel ($/kg) and concrete ($/kg), the total cost of the tower is estimated by calculating the amount of steel and concrete in the defined structure.

For an embodiment, the tower cost is computed based on unit costs (per-kg) of steel and concrete and is provided to the non-linear optimizer as an objective that needs to be minimized or reduced. Since the objective is minimized in a relative sense (based on previous iteration estimate), the relative unit-cost of steel with respect to concrete is important rather than their individual unit costs. Since the unit cost of steel is typically much more expensive than concrete, for an embodiment, the optimizer spends more effort to reduce the quantity of steel rather than concrete. For an embodiment, the optimizer 550 iteratively produces an updated design with a lower cost than the previous iteration while still satisfying constraints. For an embodiment, this process is repeated until the optimizer 550 is unable to reduce the cost further based on a % change threshold.

For an embodiment, the non-linear optimizer 550 guesses a new set of design variables based on the latest estimate of the objective 546 and constraints 245. In this case, the objective is to reduce costs and the constraints are the collection of structural failure indices. For an embodiment, the non-linear optimizer 550 generates a new design with the objective of reducing costs without violating constraints. For an embodiment, the ant-colony heuristic optimization method is used to solve this nonlinear, discrete optimization problem.

An embodiment (as additionally shown in FIG. 5) further includes estimating costs of the design of the tower. This includes further iterating the design of the tower based on the estimated costs of the wireless base station antenna tower structure, wherein the structural model is reiterated both when the nodal displacements and material failure indices indicate failure and when the cost estimates of the design of the tower exceeds a threshold. A present iteration of the antenna-supporting tower design is checked 560. For an embodiment, if the cost objectives or the failure (lack of) objectives are not met, a new set of design variables is fed back to the selection of the high-level design features 220. The loop continues until a success criterion is met: either the cost is reduced by some x % or the optimizer has run for “t” secs. The final design and cost are output to the user as a final design 570. The user can now change the requirements to generate a new design by starting a new optimization.

At least some of the described embodiments can be used to derive preliminary designs from high-level requirements in a short period of time. Preliminary designs are valuable to improve the design cycle efficiency, conduct system-level trades and can also help refine the requirements. Directly using high-fidelity analysis to design new towers from requirements is time-consuming due to the large number of variables and detail involved. Preliminary designs provide a reliable starting point for the final phase of design to further refine and validate using high-fidelity tools and can significantly save time as a result.

At least some of the described embodiments provide a method to rapidly estimate approximate structural capacity for planning purposes. At least some of the described embodiments provide an estimate of the extent of material failure and tower costs using simple design features—tower height, number of guys, antenna loading, etc. The material failure analysis is useful to provide an approximate measure of available structural capacity to support additional loading. This is useful for obtaining quick estimates where detailed design drawings are unavailable for towers. High-level features could instead be extracted form site-surveys or photos.

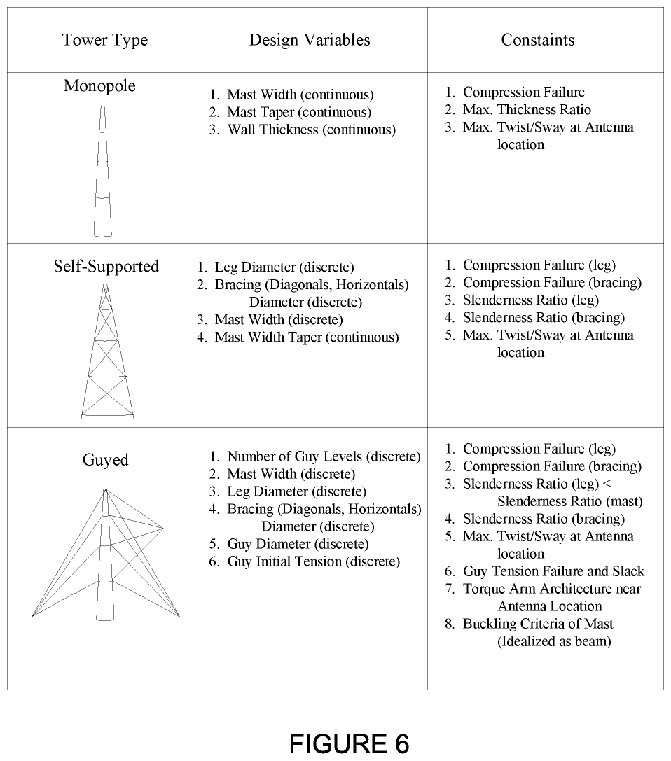

FIG. 6 illustrates several possible antenna tower structure designs and design variables and constraints associated with each of the possible antenna tower structure designs, according to an embodiment. Exemplary tower designs include a monopole antenna tower, a self-supported antenna tower, and a guyed antenna tower.

For the monopole antenna, possible design variables include a mast width (continuous), a mast taper (continuous), and wall thickness (continuous). Possible constraints on the tower design include compression failure, a maximum thickness ratio, a maximum twist/sway ratio at the antenna location.

For the self-supported antenna, possible design variables include a leg diameter (discrete), bracing (diagonals and/or horizontals) diameter (discrete), mast width (discrete), and mast width taper (continuous). Possible constraints of the tower design include compression failure (leg), compression Failure (bracing), slenderness ratio (leg), slenderness ratio (bracing), and maximum twist/sway at the antenna location.

For the guyed antenna, possible design variables include a number of guy levels (discrete), mast width (discrete), leg diameter (discrete), bracing (diagonals, horizontals) diameter (discrete), guy diameter (discrete), and guy initial tension (discrete). Possible constraints of the tower design include compression failure (leg), compression failure (bracing), slenderness ratio (leg)<slenderness ratio (mast), slenderness ratio (bracing), maximum twist/sway at the antenna location, guy tension failure and slack, torque arm architecture near the antenna location, and buckling criteria of the mast (idealized as beam).

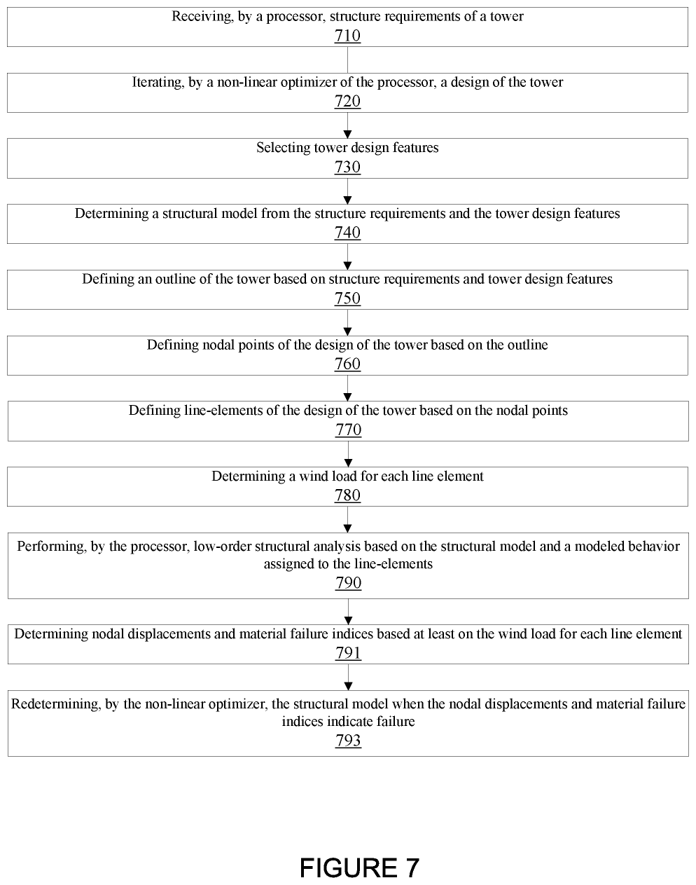

FIG. 7 is a flow chart that includes steps of a method of generating an antenna tower structure design, according to an embodiment. A first step 710 includes receiving, by a processor, structure requirements of a tower. A second step 720 includes iterating, by a non-linear optimizer of the processor, a design of the tower, including a third step 730 of selecting tower design features, a fourth step 740 of determining a structural model from the structure requirements and the tower design features, a fifth step 750 of defining an outline of the tower based on structure requirements and tower design features, a sixth step 760 of defining nodal points of the design of the tower based on the outline, a seventh step 770 of defining line-elements of the design of the tower based on the nodal points, an eighth step 780 of determining a wind load for each line element, a ninth step 790 of performing, by the processor, low-order structural analysis based on the structural model and a modeled behavior assigned to the line-elements including a tenth step 791 of determining nodal displacements and material failure indices based at least on the wind load for each line element, and an eleventh step 793 of redetermining, by the non-linear optimizer, the structural model when the nodal displacements and material failure indices indicate failure.

For an embodiment, redetermining, by the non-linear optimizer, the structural model when the nodal displacements and material failure indices indicate failure further includes reselecting the tower design features before redetermining the structural model, and reperforming the low-order structural analysis, and redetermining the nodal displacements and material failure. That is, if the material failure indices indicate failure, then the tower design features are reselected, and then the structural model is redetermined, the low-order structural analysis is reperformed, and the nodal displacements and material failure are redetermined with the reselected tower design features.

For an embodiment, assigning the modeled behavior to the line-elements includes assigning a specific stiffness to each line-element, and assigning a stress-displacement behavior to each line-element.

For an embodiment, the structure requirements of the tower include high-level design parameters including at least one of a tower height, a tower type (monopole, self-supported or guyed), a mast cross-section (triangle or square), loading (windspeed, gust amplification) or reliability (risk to property in case of crash). For an embodiment, the tower design features include at least one of mast leg and diagonal diameters, a mast size, a number of guys, a diameter of the guys.

For an embodiment, the nodal points of the design of the tower are dependent on a tower type. For an embodiment, the outline of the tower includes one of a monopole, self-supported or guyed. For an embodiment, for monopoles and guyed towers, the tower mast is assumed to be a single beam and is divided into at least 10 nodes between each breakpoint, wherein a breakpoint is a point where a guy cable attaches to the tower mast. For an embodiment, for guyed towers, one element with nodes on either end, is defined for each guy wire. For an embodiment, for the self-supported tower, the mast is assumed to be a lattice structure and nodes are defined at truss-intersection points.

For an embodiment, assigning a specific stiffness to each line-element comprises associating a tension with each line-element (guy-wire element only). For an embodiment, guy cables are modeled as tension-dependent linear springs. For an embodiment, slender lattice structures for the mast are modeled as equivalent beams.

For an embodiment, assigning a stress-displacement behavior of each line-element indicates a degree of stress induced in a structural member as the nodal points are displaced due to either being tensioned or compressed.

For an embodiment, performing, by the processor, low-order structural analysis based on the structural model and the modeled behavior assigned to the line-elements comprises determining potential constraint violations. For an embodiment, the potential constraint violations include material failure of a particular structural member, or too large an antenna displacement to maintain a wireless link.

At least some embodiments further include estimating costs of the design of the tower, and further iterating the design of the tower based on the estimated costs of the tower, wherein the structural model is reiterated when the nodal displacements and material failure indices indicate failure or when the cost estimates of the design of the tower are determined by the non-linear optimizer to be sub-optimal.

At least some embodiments further include generating, by a plurality of wind sensors, wind information of a database, wherein determining the wind load comprises accessing the wind information from the database.

### Additional Discussions

As previously described, the optimization framework is illustrated in FIGS. 2 and 5. For an embodiment, an open-source software for static and dynamic analysis of 3D truss structures, is used to build a finite-element representation of the tower structure. For an embodiment, the mast is modeled as an interconnected lattice structure or an equivalent slender-beam. For an embodiment, axial, bending and torsional stiffnesses of this equivalent beam are provided for various bracing patterns. For an embodiment, local wind speeds are estimated from a worldwide wind model using extreme value distribution statistics. For an embodiment, the tower structure is first built-up using a set of macro design variables such as face width, bracing angle, with an estimate of the structural response in terms of distributed stresses and deflections.

For an embodiment, to size the tower given design constraints, an optimization routine (such as, 250, 550) based on the ant colony optimization method is used to derive minimum cost designs. With user-defined material costs (steel and concrete) and a computed material weight, the total cost of the tower is estimated which is then provided to the optimizer as an objective. For an embodiment, constraints including material failure, buckling limits, guy slack, etc. are sent to the optimizer as constraints. The input variables are mixed continuous-discrete in nature (width of monopole, number of guy levels, etc). Accordingly, for at least some embodiments, heuristics-based optimization algorithms targeted at mixed-integer nonlinear optimization (MINLP) problems are utilized for this purpose.

For an embodiment, the flow of data is described as follows: High-level design parameters such as tower height, tower type and windspeed are fixed by the user as a set of requirements. Based on guess design variables (number of guy levels, leg sizes, etc.), the tower cost and a set of structural constraints related to failure criteria and stiffness requirements can be determined. For an embodiment, based on the objective and constraints, the final optimized design is produced. This procedure is therefore useful to quickly determine the tower costs for trade studies purposes for varying requirements (tower height, location, etc.).

### Modeling: Structures

For an embodiment, as aforementioned, the structure is modeled using a simplified finite-element method. For an embodiment, the user is provided the option to model the entire structure as a truss network or to model the mast with equivalent beam elements. Typically, monopole structures are modeled using beam elements, self-supported with a full truss network and tall guyed towers using the equivalent beam method.

For an embodiment, modeling monopoles and self-supported structures involves building up the geometry, defining elements, connections and element properties. However, modeling guyed towers involve significant complexity. The slenderness of the structure along with the significant flexibility makes them inherently sensitive to dynamic external excitation such as wind turbulence. In addition, the guy cable sag due to self-weight lends itself to nonlinear behavior under normal service conditions. Guyed towers also manifest dynamic aeroelastic behavior such as aeolian vibrations (high-frequency, low-amplitude oscillations) due to vortex shedding and galloping (large-amplitude, low-frequency oscillations).

For an embodiment, analysis of a guyed tower involves a large degree of freedom finite-element representation of the truss mast and guy cables taking into account nonlinear behavior. A complex structural model implies a detailed tower representation as an input. The design process therefore is time-consuming with many variables and requires engineering judgment to produce cost-optimized tower designs. Low-order representations of the tower behavior are sought to simplify the design process for rapid design validation and cost analysis.

For an embodiment, a full-order analysis for the truss involves idealizing every truss member (vertical, horizontal, diagonal) as beam elements. For an embodiment, as a simplification, owing to the slenderness of the mast, the truss as a composite may be idealized using equivalent beam elements. The number of beam elements should be large enough to accommodate property variations in the mast. Typically, around 10 beam elements between guy levels are considered adequate. Depending on the bracing pattern of the mast, equivalent properties of the substitute beam may be derived.

For at least some embodiments, in a similar manner, the guy cables may be idealized as linear springs. An expression for the cable stiffness considering cable geometry, self-weight and initial pre-tension (TP) is provided as follows:

EAeq=(EAg)/(1+(mgb/TP)²/(EAg/12Tₚ)) where b is the distance of the ground attachment point from the mast, Ag is the guy cross-sectional area and mg is the weight per unit length. This expression is accurate for low in-service loads compared to the pre-tension forces. Similar to idealization of beam elements, with modulus, E, known, cross-sectional areas can be computed for the truss link. For multiple cables at the same attachment points (at mast and ground), the computed areas are appropriately scaled.

For an embodiment, the tension (T) in the cables is given by:

T=TP+EA*(u/c)

where u is the linear displacement at the mast attachment point and c is the length of the cable.

For an embodiment, the calculated tension is necessary to evaluate cable failure or slack. The vertical download due to cable initial tension is given by:

T=Tₚ*(d/c)

For an embodiment, vertical dead loads (gravity, downward load due to initial cable tension) are applied as vertical axial loads at different mast elevations. Forces due to wind are applied as horizontal shearing loads on the mast. A pinned boundary condition is enforced at the mast bottom.

For an embodiment, a finite-element representation is constructed (equivalent beam elements for mast and spring elements for cables) and with the applied dead and wind loading, the system of equations is solved for to obtain internal reactions and displacements. Given internal loads developed in the mast (idealized as an equivalent beam), member stresses are then estimated.

For an embodiment, vertical members are assumed to carry compression loading due to downloads and bending moments. For the vertical leg members, axial stress is computed as follows using mast axial and bending moment loads:

F_{leg}=(⅓)*F_{mastAX}+(F_{mastBM})*(2)/(√3a)

For an embodiment, bracing members are assumed to carry shearing loads. With shearing loads, Fₓ, F_{y} and torsional moments M_{z}, F₁, F₂ and F₃ are calculated assuming static equilibrium:

F1=(2M_{z})/(√3a)+(⅔)*F_{y}

F2=(2M_{z})/(√3a)−(F_{y})/(3)+(Fₓ)/(2 sin(60 deg))

F3=(2M_{z})/(√3a)−(F_{y})/(3)−(Fₓ)/(2 sin(60 deg))

### Modeling: Aerodynamics

For an embodiment, to specify aerodynamic loading on the structure, dynamic pressure, aerodynamic coefficients and area of obstruction are required. The dynamic pressure (or equivalently wind speed) is a function of geography and altitude. ASCE prescribes design wind speeds in terms of maximum 3-second gusts at 10 m height above ground level. Wind speed data with this specification (3-second gusts) is available worldwide (given latitued/longitude) from the European Centre for Medium Range Weather Forecasts (ECMWF). For an embodiment, wind data is taken for a period of 20 years at 2-hour intervals.

For an embodiment, 50-year returns are calculated using extreme value statistics. First, maximum annual wind speeds in miles per hour is estimated and sorted (lowest to highest). A linear fit is now found between x=−ln(−ln(Pᵥ)) and the sorted windspeeds, y, such that

y=αx+β

where,

Pv=(m−0.44)/(N+0.12)

and m is the one-based index of the sorted windspeed distribution and N is the total number of annual observations. For a return period of R (typically, 50 years), the design speed over the return interval is calculated as:

Vmax=α(−ln(−ln(1−1/R)))+β.

For an embodiment, aerodynamic coefficients are dependent on the shape of the obstruction and wind direction. For an embodiment, tables are provided in the standard for various antenna shapes indexed with wind direction to determine loading. Such coefficients may also be derived for the mast structure depending on the bracing pattern for a drag coefficient of one for individual members (legs and bracing). Here, only round members are considered, i.e., steel pipes or solid rods. A drag coefficient of 1.2 is accordingly assumed. Note that for round mast members, wind direction does not significantly change the resultant wind load.

For least some embodiments, in addition to aerodynamic coefficients, several load factors can be specified to account for reliability and terrain. The structure class criteria specify load factors for varying degrees of hazard to property in case of structural failure. The exposure category adjusts wind loading to account for varying terrain: shorelines, open areas or urban. Wind speed variations in height can also be specified depending on the local terrain profile. The wind direction probability factor accounts for uncertainty in nominal local wind directions. The gust effect factor adjusts wind loads to account for wind turbulence. This factor is dependent on the tower choice: guyed vs self-supported and tower height. Load combinations are also specified to simulate limit states. A common load combination is a 1.6 multiplier on wind loads and a 1.2 multiplier on dead loads.

### Design Methodology

For an embodiment, depending on the structure type (monopoles, self-supported or guyed), certain design rules are imposed to make the search through the design space efficient. For instance, for the guyed tower, the site radius is fixed at 80% of tower height. Guy sizes are chosen such that there is minimum slack and cables are always in a state of tension. Anchor locations are chosen such that the distance from the mast equals the average attachment height of the associated guy cluster.

For an embodiment, constraints impose limits on member slenderness ratio, member stress failure and angular displacements at antenna locations. In addition, for guyed towers, a constraint is added to ensure a torque arm with double the number of guys is present near an antenna location to augment local stiffness. Design variables are specified as continuous or discrete. Discrete variables include number of guy levels as well as member sizes to reflect their availability in standard dimensions.

For an embodiment, the optimization objective to be minimized is total tower cost. This includes both material and nonmaterial costs (construction, logistics, etc). Non-material costs are scaled with tower height or applied as an overhead percentage on material costs. Unit costs for both material and non-material costs are provided by the user. For the foundation, the pad footing is sized such that tension is prevented within the concrete block which could cause the pad to crack. This is done by checking if the shear planes pass through the lower corners of the pad strip. The shear planes are assumed to be 45 deg from the base which implies that the pad thickness will equal the pad projection (D=P). The pad area is determined from the soil bearing capacity. Given the maximum download force, Fₐ, soil bearing capacity, σ_{b}, the pad area is then given by: Ap=(Fₐ)/(σ_{b}). Assuming a square pad footing, the width is then determined, based on which the pad thickness is also obtained.

For an embodiment, the anchor block dimensions sizes are similarly determined based on anchor reactions and soil properties. The results are summarized as follows:

d_{f}=(2h)*(γₛ/γ_{c})

lf=(3Pₕ)/((kₚd_{f}²)*(γₛ+γ_{c}))

b_{f}=(Pᵥ)/(d_{f}l_{f} γ_{c}) where γₛ and γ_{c} are the densities of soil and concrete respectively. Pₕ and Pᵥ are the horizontal and vertical components of the guy cable tension acting on the anchor block. In this study, the height of soil, h is assumed as 1 m.

### Application

Cell tower companies face the problem of forecasting demand and/or optimizing their inventory—i.e. the number of various types of towers that they will need to build and supply. The suitability of a tower for any particular communication network use-case will depend on the implied cost and benefit trade-off. Put simply, taller towers are generally more expensive while also being more powerful as a communications platform, due to being better from an RF (Radio Frequency) coverage perspective. Network operators are concerned with reducing their infrastructure cost and would like to utilize towers that provide the best return on invested dollar.

The tower cost optimization of the described embodiments helps with this use-case by providing insights into the distribution of cost-optimized towers across large and diverse topographies and population densities. Furthermore, this distribution can be made to depend on an end-to-end network optimization, where the benefits of tower height for line-of-sight (LOS) based microwave backhaul connectivity, in addition to RAN (Radio Access Network) coverage, are traded-off with cost.

These cost-optimized tower height (and, in general, tower type) distributions can be sliced and diced by country, market segment, etc., enabling the tower company to either maintain or be prepared to supply appropriate volumes of diverse tower stocks in different markets. This type of result can then guide the appropriate stocking of tower inventory—for e.g., if the urban buildouts are to be prioritized in upcoming roll-outs, a 50-meter tower stock would suffice to solve for 90-th percentile of the builds.

The described embodiments provide a computational framework for preliminary analysis and design of communication towers. Computational efficiency is achieved by invoking several engineering assumptions without significantly sacrificing accuracy. Design is performed using an optimization framework that seeks to minimize tower build cost while satisfying constraints imposed by civil infrastructure design standards. The modeling procedure is compared with industry-standard, higher-fidelity tools with satisfactory agreement. Design optimality is evaluated against a commonly used design reference.

Other possible embodiments include expanding the member database to include other commonly used shapes such as steel angles. Further studies evaluating the design optimality of self-supported and monopole designs are necessary. In addition, the tool will be integrated with GIS-based capabilities to directly provide users the impact of tower design on site economic viability, site planning/logistics and LOS-based coverage.

Although specific embodiments have been described and illustrated, the embodiments are not to be limited to the specific forms or arrangements of parts so described and illustrated. The described embodiments are to only be limited by the claims.

1. A method comprising:
receiving, by a processor, structure requirements of a tower;
iterating, by a non-linear optimizer of the processor, a design of the tower, comprising:
selecting tower design features;
determining a structural model from the structure requirements and the tower design features comprising:
defining an outline of the tower based on the structure requirements and the tower design features;
defining nodal points of the design of the tower based on the outline;
defining line-elements of the design of the tower based on the nodal points;
determining a wind load associated with the line-elements;
performing, by the processor, low-order structural analysis based on the structural model and a modeled behavior assigned to the line-elements comprising:
determining nodal displacements and material failure indices based at least on the wind load associated with the line-elements; and
redetermining, by the non-linear optimizer, the structural model in an instance in which the nodal displacements and the material failure indices indicate failure.

2. The method of claim 1, wherein redetermining, by the non-linear optimizer, the structural model in an instance in which the nodal displacements and the material failure indices indicate failure further comprises reselecting the tower design features before redetermining the structural model, and reperforming the low-order structural analysis, and redetermining the nodal displacements and the material failure.

3. The method of claim 1, wherein the modeled behavior assigned to the line-elements comprises:
assigning a specific stiffness to the line elements; and
assigning a stress-displacement behavior to the line-elements.

4. The method of claim 1, wherein the structure requirements of the tower include high-level design parameters including at least one of a tower height, a tower type, a mast cross-section, loading or reliability.

5. The method of claim 1, wherein the tower design features includes at least one of mast leg and diagonal diameters, a mast size, a number of guys, or a diameter of the guys.

6. The method of claim 1, wherein the nodal points of the design of the tower are dependent on a tower type.

7. The method of claim 6, wherein the outline of the tower includes one of a monopole, self-supported or guyed.

8. The method of claim 6, wherein for monopoles and guyed towers, a tower mast comprises a single beam and is divided into at least 10 nodes between breakpoints, wherein a breakpoint is a point where a guy cable attaches to the tower mast.

9. The method of claim 6, wherein for guyed towers, one element with nodes on either end, is defined for guy wires.

10. The method of claim 6, wherein for a self-supported tower, a mast comprises a lattice structure and nodes are defined at truss-intersection points.

11. The method of claim 2, wherein assigning a specific stiffness to the line-elements of guy wires comprises associating a tension with the line-elements.

12. The method of claim 11, wherein the guy wires are modeled as tension-dependent linear springs.

13. The method of claim 11, wherein slender lattice structures for a mast are modeled as equivalent beams.

14. The method of claim 2, wherein assigning a stress-displacement behavior of the line-elements indicates a degree of stress induced in a structural member as the nodal points are displaced due to either being tensioned or compressed.

15. The method of claim 1, wherein the performing, by the processor, low-order structural analysis based on the structural model and the modeled behavior assigned to the line-elements comprises determining potential constraint violations.

16. The method of claim 15, wherein the potential constraint violations include at least one material failure of a particular structural member, or too large an antenna displacement to maintain a wireless link.

17. The method of claim 1, further comprising:
estimating costs of the design of the tower; and
further iterating the design of the tower based on the estimating costs of the tower, wherein
the structural model is reiterated in an instance in which the nodal displacements and the material failure indices indicate failure or in an instance in which the estimating costs of the design of the tower are determined by the non-linear optimizer to be sub-optimal.

18. The method of claim 1, further comprising:
generating, by a plurality of wind sensors, wind information of a database; and
the determining the wind load comprises accessing the wind information from the database.

19. A network comprising:
a database;
one or more computing devices interfaced with the database configured to:
receive structure requirements of a tower;
iterate a design of the tower, comprising:
select tower design features;
determine a structural model from the structure requirements and the tower design features;
define an outline of the tower based on the structure requirements and the tower design features;
define nodal points of the design of the tower based on the outline;
define line-elements of the design of the tower based on the nodal points;
determine a wind load associated with the line-elements:
perform low-order structural analysis based on the structural model and a modeled behavior assigned to the line-elements comprising:
determine nodal displacements and material failure indices based at least on the wind load associated with the line-elements; and
redetermine the structural model in an instance in which the nodal displacements and the material failure indices indicate failure.

20. The network of claim 19, further comprising:
a plurality of sensors configured to sense wind speed over a period of time;
wherein the one or more computing devices further configured to:
receive the wind speed and store the wind speed in the database; and
determine the wind load by accessing wind information from the database.
